(19) United States
(12) Patent Application Publication
(10) Pub. No.: US 2026/0231766 A1
(43) Pub. Date: Aug. 6, 2026

(54) Semiconductor Module Arrangement Comprising at Least One Semiconductor Element

(71) Applicant: Siemens Aktiengesellschaft, Muenchen (DE)

(72) Inventor: Benjamin Sewiolo, Obermichelbach (DE)

(21) Appl. No.: 19/154,062

(22) PCT Filed: Feb. 5, 2024
(86) PCT No.: PCT/EP2024/052706

§ 371 Date: Aug. 6, 2025

(30) Foreign Application Priority Data
Feb. 7, 2023 (EP) 23155361.1

(51) Int. Cl. H10W 40/47; H10W 29/00; H10W 76/60; H10W 90/00

(52) U.S. Cl. CPC H10W 40/47; H10W 29/00; H10W 76/60; H10W 90/734

(57) ABSTRACT

A semiconductor arrangement, in particular a power semiconductor arrangement for a power converter, includes at least one semiconductor element, wherein the at least one semiconductor element is arranged in a closed housing, where the at least one semiconductor element is in direct contact with a coolant flow of an electrically insulating cooling liquid, in particular inert liquid, in order to improve the recyclability of the semiconductor arrangement.

### CROSS-REFERENCE TO RELATED APPLICATIONS

This is a U.S. national stage of application No. PCT/EP2024/052706 filed 5 Feb. 2024. Priority is claimed on European Application No. 23155361.1 filed 7 Feb. 2023, the content of which is incorporated herein by reference in its entirety.

### BACKGROUND OF THE INVENTION

### 1. Field of the Invention

The invention relates to a semiconductor arrangement, in particular a power semiconductor arrangement for a power converter, with at least one semiconductor element, where the at least one semiconductor element is arranged in a closed housing, and further relates to a power converter with at least one semiconductor arrangement of this kind.

Moreover, the invention relates to a method for producing a semiconductor arrangement, in particular a power semiconductor arrangement for a power converter, with at least one semiconductor element, where the at least one semiconductor element is arranged in a closed housing.

Furthermore, the invention relates to the use of a coolant flow of an electrically insulating cooling fluid, in particular inert fluid, for cooling a semiconductor element in a closed housing.

Moreover, the invention relates to a computer program product, which is formed as a digital twin of a semiconductor arrangement of this kind.

### 2. Description of the Related Art

Semiconductor arrangements are used in a power converter, for example. A power converter is to be understood, for example, as meaning a rectifier, an inverter, a converter or a DC voltage converter. Usually, semiconductor arrangements of this kind comprise a housing, in which at least one semiconductor element is arranged. A semiconductor element of this kind can be a transistor, among other things. Soft casting, in particular silicone casting, is usually provided within the housing to protect the at least one semiconductor element.

The published unexamined patent application WO 2022/033745 A1 describes a power module with at least one power unit, which comprises at least one power semiconductor and a substrate, where the at least one power unit is at least partially surrounded by a housing. The housing is filled with a soft casting, in particular with a silicone casting.

Environmental aspects are also becoming more and more important in electronics development. In particular, there is a focus on improved recyclability. Recyclability, but also repair effort, are improved, for example, by omitting material-fit connections, which can be produced by soldering, sintering or welding, for example.

EP 3 926 670 A1 describes a power semiconductor module with at least one power semiconductor element. In order to reduce the necessary installation space of the power semiconductor module and to increase the service life thereof, it is proposed that the at least one power semiconductor element is connected to a cooling element in an electrically insulating and thermally conductive manner via a dielectric material layer, where the dielectric material layer lies against a surface of the cooling element in a planar manner and is connected to the cooling element with a non-positive fit via a first force acting orthogonally to the surface of the cooling element.

WO 2018/046165 A1 discloses a power module with a semiconductor structural element to be contacted on the upper and lower side, where the semiconductor structural element is to be contacted electrically on the upper side by a leadframe matrix by means of contact pressure.

A soft casting is very difficult to remove, such as during recycling procedures.

### SUMMARY OF THE INVENTION

In view of the foregoing, it is an object of the present invention to improve the recyclability of a semiconductor arrangement.

This and other objects and advantages are achieved in accordance with the invention by a semiconductor arrangement in which the semiconductor element is in direct contact with a coolant flow of an electrically insulating cooling fluid, in particular inert fluid.

The objects and advantages are further achieved in accordance with the invention by a power converter with at least one semiconductor arrangement of this kind.

Moreover, the objects and advantages are achieved in accordance with the invention by methods via which the semiconductor element is brought into direct contact with a coolant flow of an electrically insulating cooling fluid, in particular inert fluid.

Furthermore, the objects and advantages are achieved in accordance with the invention by the use of a coolant flow of an electrically insulating cooling fluid, in particular inert fluid, for cooling a semiconductor element in a closed housing, where the coolant flow is in direct contact with the at least one semiconductor element.

Moreover, the objects and advantages are achieved in accordance with the invention by a computer program product, which is formed as a digital twin of a semiconductor arrangement of this kind and which is used during a simulation of the operating behavior of a correspondingly configured semiconductor arrangement.

The advantages and preferred embodiments disclosed below in relation to the semiconductor arrangement can be transferred accordingly to the power converter, the method, the use and the computer program product.

The invention is based on the consideration of improving the recyclability of a semiconductor arrangement, because a soft casting that is usually used is replaced by an electrically insulating cooling fluid. A closed housing of the semiconductor arrangement, in which at least one semiconductor element is arranged, is at least partially filled with the electrically insulating cooling fluid such that the semiconductor element is in direct contact with a coolant flow of the electrically insulating cooling fluid. For example, the semiconductor element is formed as a vertical transistor, in particular as an Insulated Gate Bipolar Transistor (IGBT) or vertical SiC-MOSFET. The housing, for example, is at least partially produced from a plastic and can be closed in a fluid-tight manner, in order to minimize a loss of the electrically insulating cooling fluid. The coolant flow of the electrically insulating cooling fluid achieves an improved heat dissipation of the at least one semiconductor element. In particular, the semiconductor element is at least partially surrounded by the coolant flow. The at least one semiconductor element can be made wet by the cooling fluid. The electrically insulating cooling fluid of the coolant flow is in particular formed as an inert fluid, which for example has a dielectric strength of at least 10 kV/mm, in particular 20 kV/mm. Among others, Galden® HS 240, 3M™ Novec™ or 3M™ Fluorinert™ are possible electrically insulating cooling fluids. A simple disassembly for repair, for refurbishing or for recycling is enabled by the housing being at least partially filled with the electrically insulating cooling fluid, where the coolant flow, in particular via the direct contacting with the at least one semiconductor element, ensures an improved removal of heat, which has a positive effect on the service life of the semiconductor arrangement, among other things, and enables higher power densities. Furthermore, there is a saving on materials and energy-intensive production processes.

In particular, the operating behavior of the semiconductor arrangement, which can be significantly influenced by the coolant flow, can be checked for plausibility by comparing against a correspondingly configured simulated semiconductor arrangement. Furthermore, a recycling process of the semiconductor arrangement can be simulated and optimized with regard to a disassembly sequence, for example. The computer program product, which is formed as what is known as a digital twin, allows at least the semiconductor arrangement to be modeled in a simulation environment. Thus, a sufficiently realistic process mapping can be provided in a simple manner. A digital twin is described in publication U.S. Publication No. 2017/286572 A1, the content of which is incorporated herein by reference in its entirety.

The computer program product can be configured in a monolithic manner, i.e., fully executable on a hardware platform. Alternatively, the computer program product can also be configured in a modular manner and can comprise a plurality of partial programs that can be executed on separate hardware platforms and work together via a communicative data connection. Such a communicative data connection can be a network connection, an Internet connection and/or a mobile radio connection. Furthermore, the operation with inclusion of the coolant flow, or the recycling of the semiconductor arrangement or even of a power converter that comprises at least a semiconductor arrangement of this kind, can be tested and/or optimized by simulation in a simple and cost-effective manner via a digital twin of this kind.

The computer program product can comprise a physics module, in which the semiconductor arrangement is at least partially mapped. To this end, the semiconductor arrangement can be reproduced, for example, in its structure and its functionality, for example, as a digital mapping that is part of the computer program product. The physics module is configured to reconstruct the electrical, thermal and/or fluid mechanics behavior of the semiconductor arrangement or of the cooling fluid therein with adjustable operating conditions. The adjustable operating conditions include, for example, an operating parameter that defines a switching behavior of the at least one semiconductor switch, an inlet temperature of the cooling fluid, a specific thermal capacity of the cooling fluid, a flow speed of the cooling fluid and/or a thermal release distribution on a surface of the at least one semiconductor element. The computer program product can have a data interface, via which corresponding data can be specified via a user input, a data connection to a real semiconductor arrangement and/or other simulation-oriented computer program products. Likewise, the computer program product can have a data interface for the output of simulation results to a user and/or other simulation-oriented computer program products. The simulation results can include a temperature distribution on a surface of the at least one semiconductor element and/or an outlet temperature of the cooling fluid. A defective semiconductor element can be identified via the computer program product, for example. Due to points that are warm in isolated locations, known as hotspots, being minimized on the at least one semiconductor element in the underlying, i.e., simulated, semiconductor arrangement, these hotspots are insignificant in the inventive computer program product. The calculation of hotspots of this kind requires increased computing effort in solutions from the prior art. The inventive computer program product can be configured such that a heat emission behavior of the at least one semiconductor element can be reconstructed as substantially even heat emission on the surface thereof. This makes it possible to reconstruct the thermal behavior of the at least one semiconductor element with reduced computing power in a rapid and realistic manner. The inventive computer program product is substantially suitable for real-time monitoring of the underlying semiconductor arrangement. As a consequence, the underlying semiconductor arrangement can be thermally monitored with increased accuracy, which in turn allows longer operation with rapid load switching with increased amplitude. Overall, the underlying semiconductor arrangement is formed in a simulation-friendly manner and, as a result, its technical potential can be utilized to a greater extent. The computer program product can comprise program code, which is stored on a non-volatile memory and can be executed by a computer.

In a further embodiment, the semiconductor element is connected to a carrier element with a non-positive fit, in particular via a first press contact. A press contact of this kind can be formed, among other ways, as a power rail, also referred to as busbar. Alternatively, it is possible to use a spring, a screw and/or a bracket for the non-positive connection of the semiconductor element. A non-positive connection of the semiconductor element of this kind is detachable and simple to remove when disassembling for repairs, for refurbishing or for recycling, in particular in combination with the filling with the electrically insulating cooling fluid.

In a further embodiment, the carrier element is produced from a metallic material, where the semiconductor element is connected to the carrier element in an electrically insulating manner via a dielectric material layer. The carrier element can contain copper, aluminum or one of the alloys thereof, among other things. The dielectric material layer can contain aluminum oxide, aluminum nitride or an organic electrically insulating and thermally conductive material, among other things, in order to connect the semiconductor element to the carrier element in an electrically insulating and thermally conductive manner. In this manner, heat dissipation of the semiconductor element can additionally take place via the carrier element.

In yet a further embodiment, the carrier element comprises at least one channel, through which the coolant flow passes. For example, the channel, through which the electrically insulating cooling fluid flows, is formed in a meandering manner, so that the heat occurring during the operation of the semiconductor element is dissipated efficiently in a bilateral manner by the coolant flow.

In a still further embodiment of the inventive semiconductor arrangement, the at least one semiconductor element can be made wet by the coolant. In particular, it is possible for the coolant flow to wash around the at least one semiconductor element at least partially, here. Through direct contact of this kind, particularly with the presence of a coolant flow, increased heat dissipation is ensured. This utilizes the cooling fluid to a greater extent from a thermal perspective. In particular, this minimizes points that are warm in isolated locations, known as hotspots, on the at least one semiconductor element. These kinds of points that are warm in isolated locations on the at least one semiconductor element can occur, for example, during high electrical loads, in particular rapid load switching with increased amplitude. The corresponding points that are warm in isolated locations can be determinative for the thermal configuration of the semiconductor arrangement. Due to the at least one semiconductor element being made wet by the cooling fluid, the technical potential of the semiconductor arrangement can be utilized to a greater extent.

In another embodiment, the semiconductor arrangement comprises a second guide apparatus, which is configured to guide the coolant flow, which passes through the at least one channel of the carrier element, over the semiconductor element. A guide apparatus of this kind can be formed, among other ways, as a guide plate and is used to bring the coolant flow in contact with the semiconductor elements in a targeted and even manner.

In a further embodiment, on a side of the carrier element facing away from the semiconductor element, a further semiconductor element is connected to the carrier element with a non-positive fit, in particular via a first press contact. A bilateral arrangement of the semiconductor elements of this kind leads to a higher integration density or power density of the arrangement. Furthermore, a bilateral non-positive connection of the semiconductor elements to the carrier element is simple to remove, which additionally simplifies the disassembly for the sake of repairs, for refurbishing or for recycling.

In another embodiment, the electrically insulating cooling fluid comprises a phase-change coolant. For example, inert fluid such as 3M™ Novec™ is available, which has different boiling points. Thus, the boiling point can be configured such that the inert fluid functions as evaporation coolant or phase-change coolant, in order to soften thermal peaks, for example. The phase-change cooling enables higher heat transfer coefficients, particularly compared to purely sensible cooling.

In a still further embodiment, a condensation apparatus for condensing an evaporated coolant is arranged in the closed housing. The condensation apparatus can have a heat exchanger, among other things. An arrangement of this kind enables condensation with the presence of inert gases, in particular air, close to ambient pressure, by the inhibiting effect of inert gases being avoided through mixing.

In a further embodiment, a sensor is arranged in the region of the semiconductor element, where the coolant flow is regulated based on sensor data, which is ascertained with the aid of the sensor. The sensor can comprise a temperature sensor, a voltage sensor and/or a current sensor, among other things. A regulation of the coolant flow of this kind makes it possible, for example, to keep the temperature of the semiconductor element within a predetermined temperature range.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention will now be described and explained in greater detail making reference to the exemplary embodiments illustrated in the figures, in which:

FIG. 1 shows a schematic cross-sectional representation of a first embodiment of an inventive semiconductor arrangement;

FIG. 2 shows a schematic cross-sectional representation of a second embodiment of an inventive semiconductor arrangement;

FIG. 3 shows a schematic representation of a third embodiment of an inventive semiconductor arrangement;

FIG. 4 shows a schematic representation of a fourth embodiment of an inventive semiconductor arrangement;

FIG. 5 shows a schematic representation of an inventive power converter; and

FIG. 6 is a flowchart of the method in accordance with the invention.

### DETAILED DESCRIPTION OF THE EXEMPLARY EMBODIMENTS

The exemplary embodiments explained below involve preferred embodiments of the invention. In the exemplary embodiments, the described components of the embodiments each represent individual features of the invention that are to be regarded as independent of one another and each also develop the invention independently of one another and are thus also to be considered individually, or in a combination different from that shown, as a constituent part of the invention. Furthermore, the embodiments described can also be enhanced by further features of the invention of those already described.

The same reference characters have the same meaning in the different figures.

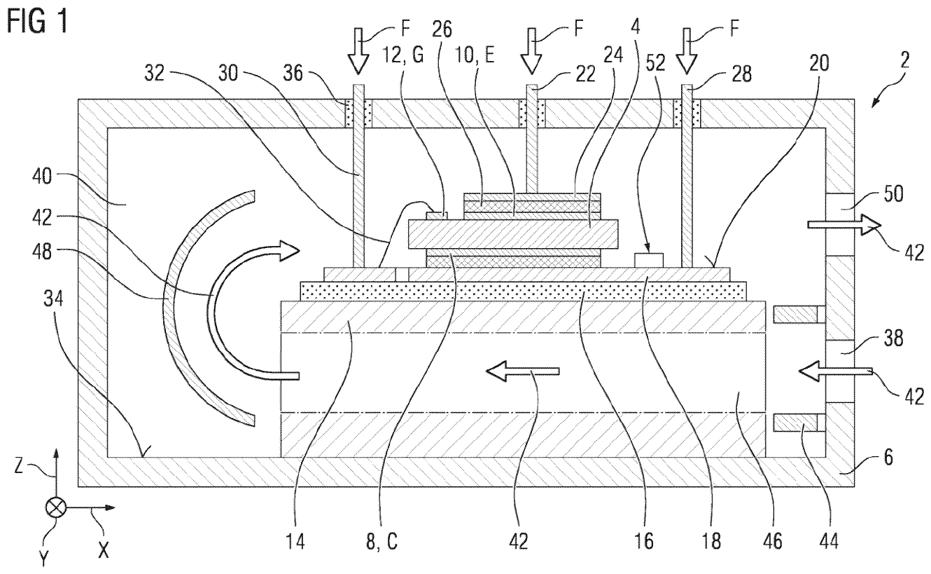

FIG. 1 shows a schematic sectional representation of a first embodiment of a semiconductor arrangement 2 with a semiconductor element 4, which is arranged in a closed housing 6. For example, the semiconductor element 4 is formed as a vertical transistor, in particular as an Insulated Gate Bipolar Transistor (IGBT) or vertical SiC-MOSFET. The semiconductor element 4 has a first power contact 8, in particular a collector contact C, and a second power contact 10, in particular an emitter contact E, on an opposite side, and a control contact 12, in particular a gate contact G.

The housing 6 is produced from a plastic, for example. Moreover, arranged in the housing 6 is a carrier element 14, which is formed as a metallic cooling body. The cooling body is produced from copper, aluminum or one of the alloys thereof, for example. Arranged on the cooling body are a dielectric material layer 16, which in particular contains aluminum oxide, aluminum nitride or an organic electrically insulating and thermally conductive material, and a metallization 18, which for example contains copper, gold, molybdenum, silver or one of the alloys thereof. The metallization 18 has a flat surface 20, which defines an xy-plane as well as a z-axis standing perpendicularly to the surface 20. The dielectric material layer 16 can be connected to the cooling body in a pressed-in or adhesive manner. Alternatively, a substrate, in particular a Direct Copper Bonded (“DCB”) substrate, can be arranged on the cooling body. The substrate can be connected with a material fit, for example, by soldering on the cooling body, among other ways.

The semiconductor element 4 is connected to the carrier element 14 with a non-positive fit via a first press contact 22 via the dielectric material layer 16. With the dielectric material layer 16, an electrically insulating and thermally conductive connection is produced between the semiconductor element 4 and the carrier element 14. Transferred via the first press contact 22 is a force F which acts orthogonally to the surface 20 and via which the semiconductor element 4 is fixed to the carrier element 14.

A metallic contacting element 24 is connected to the second power contact 10 of the semiconductor element 4 and functions as a buffer layer, which distributes the force F from the press contact 22, so that an introduction of pressure peaks into the sensitive semiconductor element 4 is prevented. The metallic contacting element 24 can be formed, among other things, as a small metal plate that contains copper and/or molybdenum and can have a thickness in the range of 25 μm to 250 μm. The connection of the metallic contacting element 24 to the semiconductor element 4 occurs with a material fit via a sinter layer 26, but can also occur by soldering. Alternatively, the metallic contacting element 40 can be sprayed-on via a thermal spraying method, in particular in the form of copper and/or molybdenum particles.

In addition to the mechanical fixing, the electrical contacting of the power contact 10 of the semiconductor element 4 occurs via the first press contact 22. A plurality of first press contacts 22, arranged in a square or rectangular shape on the metallic contacting element 24, in particular equidistantly, (for example, 2×2, 2×3, 3×3, 3×4 or 4×4) leads to an improved mechanical fixing of the semiconductor element 4, a more homogeneous pressure distribution and a low-resistance electrical contacting. A second press contact 28 and a third press contact 30 are connected with a non-positive fit to the surface 20 of the metallization 18 for electrically contacting the first power contact 8 or the control contact 12, where the control contact 12 is connected to the metallization 18 via at least one wiring structure 32. The at least one wiring structure 32 is formed as a bond wire or bond band, for example, which in particular is welded by ultrasonic wire bonding. The carrier element 14 is pressed onto the inner wall 34 of the housing 6 via the press contacts 22, 28, 30. Additionally, the carrier element 14 can be connected to the inner wall 34 of the housing 6 with a material fit, for example, via adhesion.

The press contacts 22, 28, 30 are formed as power rails, which are also referred to as busbars. For example, the power rails are produced from copper or a copper alloy. Additionally or alternatively, the press contacts 22, 28, 30 can have a spring, a screw a bracket. The power rails are guided out from the housing 6 via sealing elements 36, so that the housing 6 is sealed off in a water-tight, in particular fluid-tight, manner.

An electrically insulating cooling fluid 40 is supplied via an intake 38, where a coolant flow 42 is generated and the housing 6 is filled, in particular fully, with the electrically insulating cooling fluid 40. The coolant flow 42 is guided via a first guide apparatus 44, which is connected to the housing 6 and/or the carrier element 14, for example, through at least one channel 46, which is arranged such that it passes through the carrier element 14. The first guide apparatus 44 can comprise guide plates and/or a pipe, for example. The channel 46 can extend in a meandering manner through the carrier element 14, among other ways. The coolant flow 42 emerging from the channel 46 of the carrier element 14 is diverted via a second guide apparatus 48, which is formed as a guide plate, for example, so that the electrically insulating cooling fluid 40 flows via the semiconductor element 4, so that the semiconductor element 4 is in direct contact with the coolant flow 42. For example, the semiconductor element 4 is formed in a substantially square-shaped manner, where at least five of the six side areas of the square-shaped semiconductor element 4 are in contact with the electrically insulating cooling fluid 40. Furthermore, the four side areas of the semiconductor element 4 formed in a square-shaped manner, which are arranged such that they extend perpendicularly to the xy-plane, are fully contacted by the electrically insulating cooling fluid 40. The cooling fluid 40 that has been heated by the waste heat occurring during the operation of the semiconductor element 4 is discharged via a drain 50, is cooled outside of the housing 6 and is re-supplied via the intake 38.

The electrically insulating cooling fluid 40 comprises an inert fluid, which has a high dielectric strength of at least 10 kV/mm, in particular 20 kV/mm. Among others, Galden® HS 240, 3M™ NoveC™ or 3M™ Fluorinert™ are possible as electrically insulating cooling fluids 40. The electrically insulating cooling fluid 40 replaces a casting mass that is usually used in the semiconductor arrangement 2 and that is produced from a silicone insulation material that is difficult to remove, for example. The electrically insulating cooling fluid 40 can be removed from the housing 6 in a very simple manner, so that the components in the housing 6 are freely accessible for recycling and repair procedures. An improved heat dissipation during the operation of the semiconductor arrangement 2 is achieved by the coolant flow 42, which is in direct contact with the semiconductor element 4. Immersion cooling of this kind makes it possible to disassemble the semiconductor arrangement 2 in a simple and at least largely reversible manner, in particular for recycling and repair procedures.

A sensor 52, which can comprise a temperature sensor, a voltage sensor and/or a current sensor, among other things, is arranged in the region of the semiconductor element 4. The coolant flow 42 is regulated with the aid of sensor data that has been ascertained with the aid of the sensor 52, in order to keep a temperature of the semiconductor element 4 within a predetermined temperature range, for example.

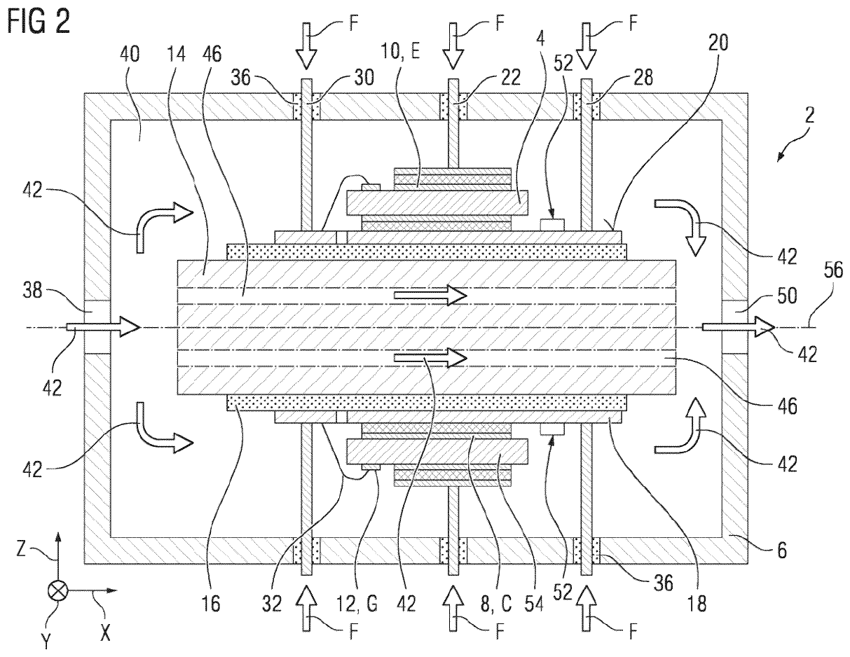

FIG. 2 shows a schematic sectional representation of a second embodiment of a semiconductor arrangement 2. A further semiconductor element 54 is connected to the carrier element 14 with a non-positive fit on a side, which faces away from the semiconductor element 4, of the carrier element 14 that is arranged substantially centrally in the housing 6 in the z-direction. Thus, the semiconductor elements 4, 54 are arranged bilaterally on the carrier element 14, which is kept substantially centrally in the housing 6 by the press contacts 22, 28, 30. The semiconductor arrangement 2 is arranged substantially with axial symmetry in relation to a central axis 56. The electrically insulating cooling fluid 40 of the coolant flow 42 is guided substantially symmetrically over the semiconductor elements 4, 54 and through the channels 46 of the carrier element 14 that are arranged with axial symmetry around the central axis 56, so that an even heat dissipation of the semiconductor elements 4, 54 in direct contact with the coolant flow 42 takes place. As in FIG. 1, the arrangement can have guide apparatuses, such as guide plates, in order to bring the coolant flow 42 into contact with the semiconductor elements 4, 54 in a targeted and even manner. The further configuration of the semiconductor arrangement 2 in FIG. 2 corresponds to the design in FIG. 1.

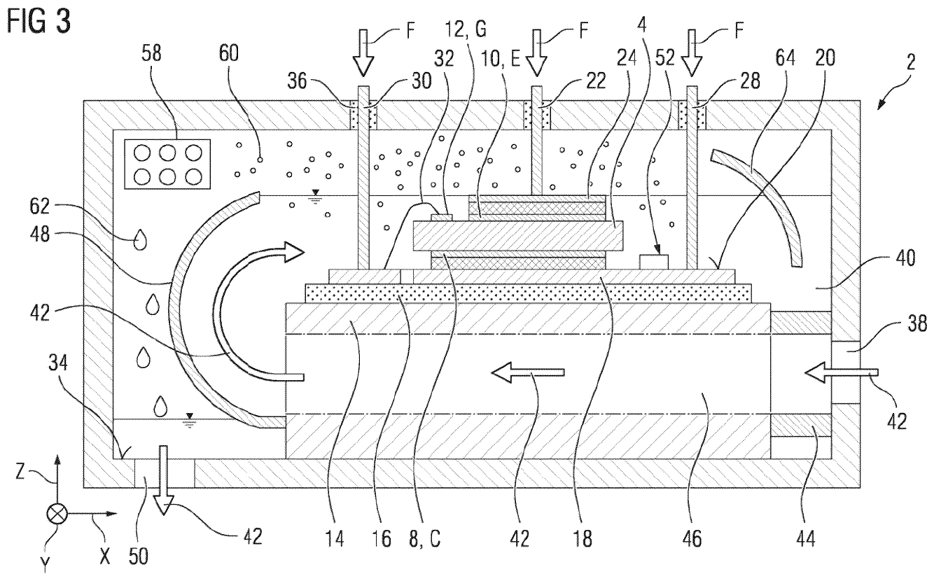

FIG. 3 shows a schematic representation of a third embodiment of a semiconductor arrangement 2, where at least part of the electrically insulating cooling fluid 40 evaporates on direct contact with the semiconductor element 4. The cooling fluid 40 is an inert fluid, such as 3M™ Novec™, for example, the boiling point of which is configured such that it functions as evaporation coolant or phase-change coolant. For example, the boiling point lies at 61, 76 or 91° C. Through a phase-change cooling of this kind, it is possible to soften thermal peaks, for example. Via a condensation apparatus 58, in particular a heat exchanger, the evaporated coolant 60 is condensed and re-supplied to the circuit as condensed coolant 62. The coolant flow 42 of the cooling fluid 40 that has been heated by the waste heat occurring during the operation of the semiconductor element 4, but has not evaporated, is guided to a common drain 50 via a third guide apparatus 64. Alternatively, the housing can have a separate drain for the condensed coolant 62. The further configuration of the semiconductor arrangement 2 in FIG. 3 corresponds to the design in FIG. 1.

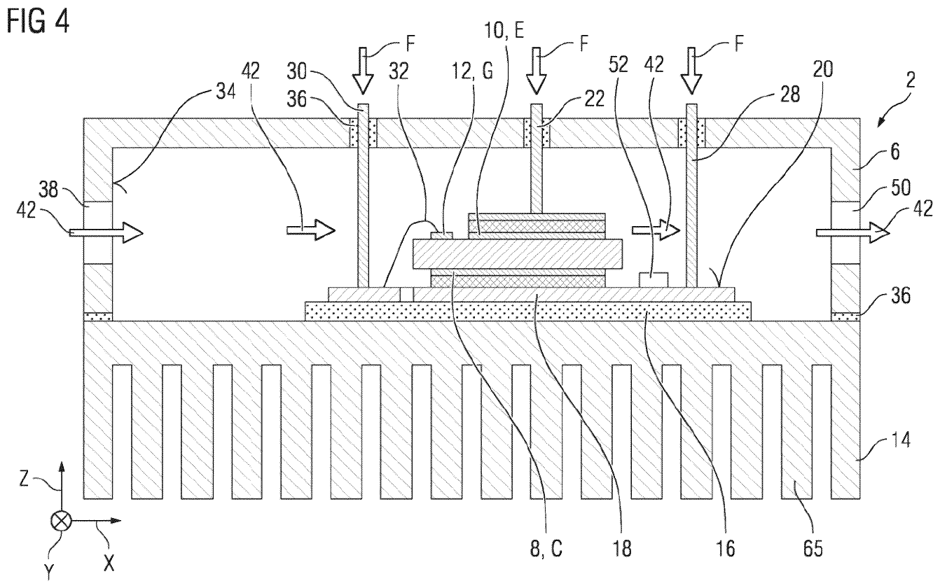

FIG. 4 shows a schematic representation of a fourth embodiment of a semiconductor arrangement 2, where the housing 6 is closed, in particular in a fluid-tight manner, via a connection to the carrier element 14. A fluid-tight, in particular adhesive, connection of the housing 6 to the carrier element 14 is produced via at least one sealing element 36. The sealing element 36 can have a sealing adhesive, for example. Alternatively, the sealing element 36 can comprise a circumferential sealing band, where the housing 6 is pressed against the cooling body via the sealing band and is closed in a fluid-tight manner in this way. For example, screws or clamps can connect the housing 6 to the cooling body in a lasting and detachable manner. The carrier element 14 is formed, by way of example, as a cooling body that is produced from copper, aluminum or one of the alloys thereof. The cooling body has fins 65, via which the heat occurring during the operation of the semiconductor element 4 can additionally be emitted to the surrounding air. The coolant flow 42 within the housing 6 runs substantially in the x-direction. The further configuration of the semiconductor arrangement 2 in FIG. 4 corresponds to the configuration in FIG. 1.

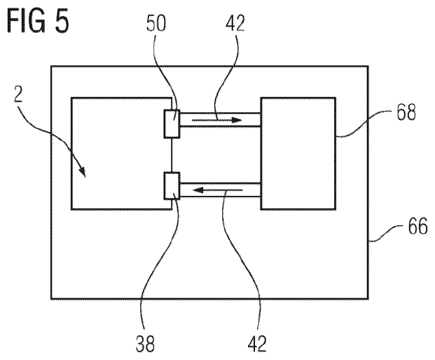

FIG. 5 shows a schematic representation of a power converter 66, which comprises a semiconductor arrangement 2 as well as a cooling apparatus 68. The coolant flow 42 emitted from the drain 50 from the semiconductor arrangement 2 is cooled via the cooling apparatus 68, which comprises a heat exchanger for example, and is re-supplied via the intake 38. The power converter 66 can comprise more than one semiconductor arrangement 2, which embody a cooling circuit with at least one cooling apparatus 68.

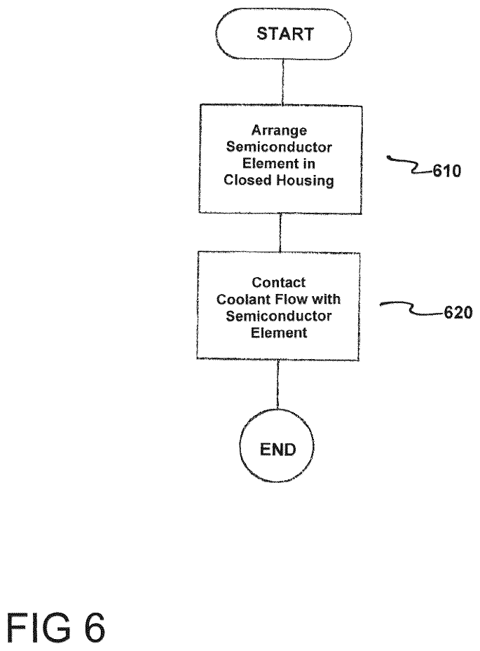

FIG. 6 is a flowchart of the method for cooling a semiconductor element 4 in a semiconductor arrangement 2 with at least one semiconductor element 4. The method comprises arranging the at least one semiconductor element 4 in a closed housing 6, as indicated in step 610. Next, the semiconductor element 4 is brought into direct contact with a coolant flow 42 of an electrically insulating cooling fluid 40, as indicated in step 620.

In accordance with the inventive method, the at least one semiconductor element 4 is connected with a non-positive fit to a carrier element 14, which is arranged in the closed housing 6, and which comprises at least one channel 46 through which the coolant flow 42 passes. In addition, the at least one semiconductor element 4 is made wetted by the cooling fluid 40.

In summary, the disclosed embodiments of the invention relate to a semiconductor arrangement 2, in particular power semiconductor arrangement for a power converter 66, with at least one semiconductor element 4, where the at least one semiconductor element 4 is arranged in a closed housing 6. In order to improve the recyclability of the semiconductor arrangement 2, the semiconductor element 4 is placed into direct contact with a coolant flow 42 of an electrically insulating cooling fluid 40, in particular inert fluid.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps that perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1-20. (canceled)

21. A semiconductor arrangement comprising:
at least one semiconductor element arranged in a closed housing;
wherein the at least one semiconductor element is in direct contact with a coolant flow of an electrically insulating cooling fluid, and the at least one semiconductor element is connected with a non-positive fit to a carrier element, which is arranged in the closed housing, and which comprises at least one channel through which the coolant flow passes; and
wherein the at least one semiconductor element is made wet by the cooling fluid.

22. The semiconductor arrangement as claimed in claim 21, wherein the at least one semiconductor element is connected to the carrier element with a non-positive fit via a first press contact.

23. The semiconductor arrangement as claimed in claim 22, wherein the first press contact is guided through a sealing element which is accommodated in a wall of the housing.

24. The semiconductor arrangement as claimed in claim 22, wherein the carrier element is produced from a metallic material; and wherein the at least one semiconductor element is connected to the carrier element in an electrically insulating manner via a dielectric material layer.

25. The semiconductor arrangement as claimed in claim 22, wherein the carrier element is produced from a metallic material; and wherein the at least one semiconductor element is connected to the carrier element in an electrically insulating manner via a dielectric material layer.

26. The semiconductor arrangement as claimed in claim 22, further comprising:
a second guide apparatus which is configured to guide the coolant flow, which passes through the at least one channel of the carrier element, over the at least one semiconductor element.

27. The semiconductor arrangement as claimed in claim 24, further comprising:
a second guide apparatus which is configured to guide the coolant flow, which passes through the at least one channel of the carrier element, over the at least one semiconductor element.

28. The semiconductor arrangement as claimed in claim 22, wherein a further semiconductor element is connected to the carrier element with a non-positive fit on a side, which faces away from the at least one semiconductor element, of the carrier element.

29. The semiconductor arrangement as claimed in claim 21, wherein the electrically insulating cooling fluid comprises a phase-change coolant.

30. The semiconductor arrangement as claimed in claim 29, further comprising:
a condensation apparatus for condensing an evaporated coolant arranged in the closed housing.

31. A power converter with at least one semiconductor arrangement as claimed in claim 21.

32. A method for cooling a semiconductor element in a semiconductor arrangement with at least one semiconductor element, the method comprising:
arranging the at least one semiconductor element in a closed housing; and
bringing the semiconductor element into direct contact with a coolant flow of an electrically insulating cooling fluid;
wherein the at least one semiconductor element is connected with a non-positive fit to a carrier element, which is arranged in the closed housing, and which comprises at least one channel through which the coolant flow passes; and
wherein the at least one semiconductor element is made wetted by the cooling fluid.

33. The method as claimed in claim 32, wherein the semiconductor element is connected to a carrier element with a non-positive fit via a first press contact.

34. The method as claimed in claim 33, wherein the coolant flow is guided through at least one channel of the carrier element.

35. The method as claimed in claim 34, wherein the coolant flow, which is guided through the at least one channel of the carrier element, is guided over the semiconductor element via a second guide apparatus.

36. The method as claimed in claim 32, wherein a further semiconductor element is connected to the carrier element with a non-positive fit comprising a first press contact, on a side, which faces away from the semiconductor element, of the carrier element, wherein the coolant flow is guided.

37. The method as claimed in claim 32, wherein a phase-change cooling occurs via the electrically insulating cooling fluid.

38. The method as claimed in claim 32, wherein a sensor is arranged in a region of the at least one semiconductor element; and wherein the coolant flow is regulated with the aid of sensor data ascertained with the aid of the sensor.

39. A computer program product comprising a digital twin of the semiconductor arrangement as claimed in claim 21 and which is utilized during a simulation of an operational behavior of a correspondingly configured semiconductor arrangement.
